(19) United States
(12) Patent Application Publication
(10) Pub. No.: US 2009/0152730 A1
(43) Pub. Date: Jun. 18, 2009

(54) Interconnected structure for TFT-array substrate

(75) Inventors: Hsin-Li Chen, Miao-Li (TW); Chao-Chih Lai, Miao-Li (TW); Ya-Chu Fan, Miao-Li (TW); Chao-Yi Hung, Miao-Li (TW); Tsau-Hua Hsieh, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 12/316,607

(22) Filed: Dec. 15, 2008

(30) Foreign Application Priority Data
Dec. 14, 2007 (CN) 200710125119.1

(51) Int. Cl. H01L 23/535

(52) U.S. Cl. 257/773; 257/E23.168

(57) ABSTRACT

An exemplary interconnected structure for transferring a voltage signal to a thin film transistor (TFT) array substrate includes a first metal layer (310), a second metal layer (320) isolated from the first metal layer and a conductive layer (340) isolated from the second metal layer. The first metal layer is electrically connected to the conductive layer via at least one first contact hole (351, 352) thereby obtaining a first contacting area between the first metal layer and the conductive layer. The second metal layer is electrically connected to the conductive layer via at least one second contact hole (353, 354) thereby obtaining a second contacting area between the second metal layer and the conductive layer. A radio of the sum of the first contacting area and the second contacting area to the voltage value of the voltage signal is equal to or greater than 0.233 μm²/mv.

### FIELD OF THE INVENTION

The present invention relates to a circuit layout of a flat display panel, and particularly to an interconnected structure for peripheral circuits on a thin film transistor (TFT) array substrate for a flat display panel.

### GENERAL BACKGROUND

Currently, flat display panels are widely used in various applications with liquid crystal displays (LCDs) a popular choice. A typical TFT-LCD panel includes an upper substrate and a lower substrate with liquid crystal materials filled therebetween. The upper substrate is typically known as a color filter substrate and the lower substrate is an array having thin film transistors thereon. A backlight module is located at the back of the TFT-LCD panel to provide a plane light source. When a voltage is applied to a transistor, an alignment of the liquid crystal is altered, allowing light to pass through to form a pixel. The upper substrate gives each pixel its own color. Combination of these pixels in different colors forms images on the TFT-LCD panel.

In addition to the TFT array formed on a display area defined by an overlapped part between the upper substrate and the lower substrate, peripheral circuits are also disposed on a non-displaying area of the lower substrate, such as driving circuits, scanning circuits and electrostatic discharge (ESD) protection circuits. The peripheral circuits on the non-displaying area can either be fabricated simultaneously with or separately from the TFT array on the display area.

FIG. 4 is a cross-section of a typical interconnected structure of a partial peripheral circuit in a non-displaying area of a TFT array substrate. A buffer layer 110, an oxide layer 120, a first metal layer 130, an insulating layer 140, and a second metal layer 150 are disposed sequentially on a surface of the non-displaying area of a TFT array substrate 100. The first metal layer 130 and the second metal layer 150 are electrically interconnected via a contact hole 151.

Because of the requirement for high resolution, the number of the interconnected structures in the non-displaying area is increased. Thus, areas of the contact holes are limited. However, when an LCD panel employing the TFT array substrate 100 works at high ambient temperatures (≧60° C.) for a long time (≧48 hours), part of the interconnected structures configured to provide a higher power voltage, such as 3.3V or 5V, to the peripheral circuit are incidentally corroded by ambient moisture and stronger electric field stress. Therefore, an interface between the first metal layer 130 and the contact hole 151 is often damaged. In some serious cases, the first metal layer 130 and the second metal layer 150 may short-circuit, thereby reducing the yield of the LCD panel.

What is needed, therefore, is an interconnected structure for TFT array substrate that can overcome the above-described deficiencies.

### SUMMARY

In one embodiment, an interconnected structure for transferring a voltage signal includes a first metal layer, a second metal layer isolated from the first metal layer and a conductive layer isolated from the second metal layer. The first metal layer is electrically connected to the conductive layer via at least one first contact hole thereby obtaining a first contacting area between the first metal layer and the conductive layer. The second metal layer is electrically connected to the conductive layer via at least one second contact hole thereby obtaining a second contacting area between the second metal layer and the conductive layer. A radio of the sum of the first contacting area and the second contacting area to the voltage value of the voltage signal is equal to or greater than 0.233 μm²/mv.

Other novel features and advantages will become more apparent from the following detailed description when taken in conjunction with the accompanying drawings. In the drawings, all the views are schematic.

### BRIEF DESCRIPTION OF THE DRAWINGS

FIG. 1 is an enlarged, top view of an interconnected structure according to a first embodiment of the present disclosure.

FIG. 2 is an enlarged, cross-sectional view taken along line II-II of FIG. 1.

FIG. 3 is a cross-section view of an interconnected structure according to a second embodiment of the present disclosure.

FIG. 4 is a cross-section of a conventional interconnected structure of a partial peripheral circuit in a non-displaying area of a TFT array substrate.

### DETAILED DESCRIPTION OF PREFERRED EMBODIMENTS

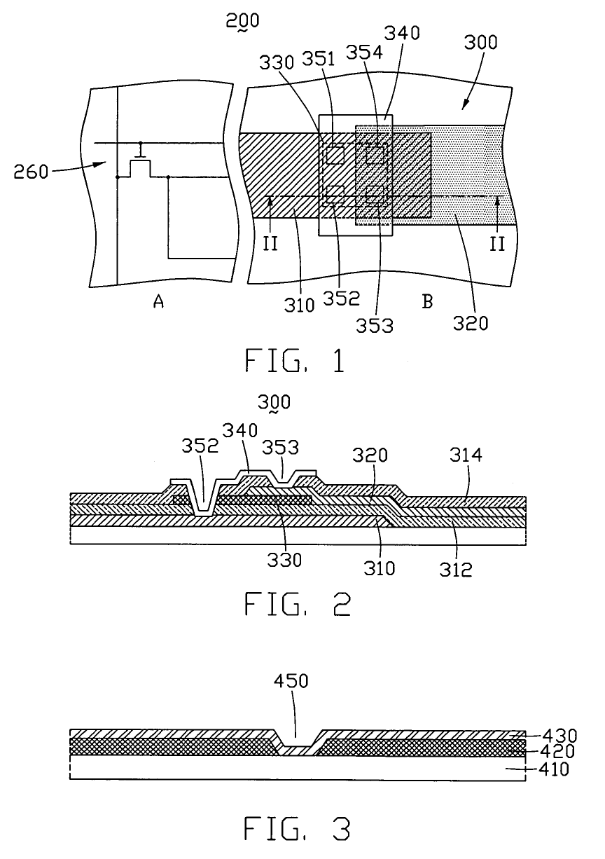

Referring to FIG. 1, an enlarged top view of an interconnected structure according to one embodiment of the invention is shown. A rear glass substrate 200 for an LCD panel is provided, and divided into a displaying area A and a non-displaying area B. A TFT array 260 is disposed in the displaying area A and a peripheral circuit (not labeled) is disposed in the non-displaying area B. The peripheral circuit includes several sets of interconnected structures and a plurality of driving circuits (not shown). In this embodiment, one set of the interconnected structure 300 configured for providing a 5V voltage signal, to the driving circuits is shown.

Referring also to FIG. 2, the interconnected structures 300 includes a first metal layer 310, an insulating layer 312, a second metal layer 320, a passivation layer 314, a semiconductor layer 330, a transparent conductive layer 340, a first pair of contact holes 351, 352, and a second pair of contact holes 353, 354. The first metal layer 310 and the second metal layer 320 are isolated from each other with the insulating layer 312. One end of the first metal layer 310 overlaps with or crosses one end of the second metal layer 320 for interconnection. The semiconductor layer 330 is disposed on a surface of the insulating layer 312 and crosses with the end of the second metal layer 320. The passivation layer 314 covers the surface of the rear glass substrate 200 having the insulating layer 312, the semiconductor layer 330 and the passivation layer 314. The first pair of the contact holes 351, 352 penetrates the passivation layer 314, the semiconductor layer 330 in a thickness direction of the rear glass substrate 200, thereby exposing where the first metal layer 310 is connected. The second pair of the contact holes 353, 354 penetrates the passivation layer 314, thereby exposing where the second metal layer 320 is connected. The end of the first metal layer 310 and the end of the second metal layer 320 are connected by the transparent conductive layer 340 that continuously covers internal surfaces of the contact holes 351˜354. The sum of x and y is 1250 μm², wherein x denotes a first contacting area between the first metal layer 310 and the transparent conductive layer 340, and y denotes a second contacting area between the second metal layer 320 and the transparent conductive layer 340. As shown in FIG. 1, the contact holes 351˜354 are homolographic squares, and side lengths of the homolographic square can be 20 μm. However, the contact holes 351˜354 can be formed in other enclosed shapes and the invention is not limited thereto.

Some sets of interconnected structures for providing higher voltage signals, such as 3.3V or 1.8V, to the driving circuit have the same structure as the interconnected structure 300. Areas of other interconnected structures that transfer relative lower voltage signals can be designed smaller than that of the sets of interconnected structures for transferring the higher voltage signals. Therefore, an area of the non-displaying area B can be limited in a proper range. In addition, the sum of the first contacting area and the second contacting area can be increased by increasing the number of the contact holes of the sets of interconnected structures, in order to maintain an original area of the non-displaying area B. For example, when the number of contact holes is 12, the side length of each contact hole can be 11 μm.

Because the interconnected structure 300 configured for providing 5V power voltage signal has a proper contacting area between the transparent conductive layer 340 and the first metal layer 310 or the second metal layer 320, a lower electric stress, approximately 0.25 μm²/mv, is taken by the interconnected structure 300. Thus, even though the LCD panel employing the rear glass substrate 200 works in a terrible environment with high ambient temperatures (≧60° C., e.g. 80° C.) for a long time (≧48 hours, e.g. 240 hours), the interconnected structure 300 can not be corroded.

Table 1 shows a testing result of corroded level, when several sets of interconnected structures having different contacting areas are at 80° C. ambient temperature and 90% ambient humidity. Wherein a capital letter “U” denotes a voltage signal provided to the set of interconnected structure, a capital letter “H” denotes a testing time, a capital letter “S” denotes the sum of the first contacting area and the second contacting area, a capital letter “R” denotes a ratio of the sum of the first contacting area and the second contacting area to a voltage value of the voltage, and a capital letter “G” denotes the testing result including three grades. Particularly, a phase “Grade 0” denotes that the set of interconnected structure is not corroded and therefore the LCD panel employing it can normally work; a phase “Grade 1” denotes that an interface between the transparent conductive layer and the first metal layer or the second metal layer is slightly corroded and therefore displaying images of the LCD panel employing the interconnected structure may generate a defect of mura; and a phase “Grade 2” denotes that the interface is seriously corroded and therefore the set of interconnected structure is a short circuit.

TABLE 1

| U (V) | H hours) | S (μm²) | R (μm²/mv) | G |
|---|---|---|---|---|
| 3.3 | 48 | 585 | 0.177 | Grade 1 |
| 5 | 48 | 585 | 0.117 | Grade 2 |
| 3.3 | 240 | 768 | 0.233 | Grade 0 |
| 5 | 240 | 768 | 0.153 | Grade 1 |
| 3.3 | 240 | 1250 | 0.413 | Grade 0 |
| 5 | 240 | 1250 | 0.250 | Grade 0 |

According to the testing result, a conclusion is obtained. That is if the ratio R is equal to or greater than 0.233 μm²/mv, a corresponding set of the interconnected structure is not liable to be corroded. Accordingly, a reliability of the LCD panel employing the set of the interconnected structure is improved.

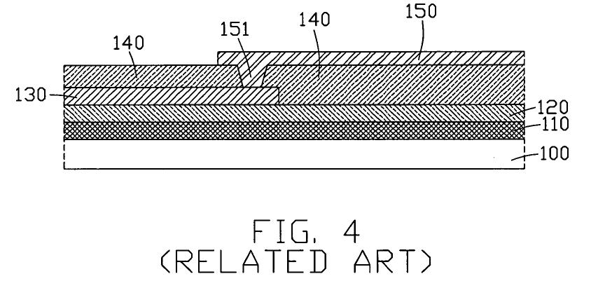

Referring to FIG. 3, another interconnected structure 400 includes a first conductive layer 410, a second conductive layer 430, an insulating layer 420 and a contact hole 450. The insulating layer 420 covers a surface of the first conductive layer 410. The contact hole 450 penetrates the insulating layer 420 in a thickness direction thereby exposing where the first conductive layer 410 and the second conductive layer 430 are electrically connected. The second conductive layer 430 continuously forms a surface of the insulating layer 420 and an internal surface of the contact hole 450. Referring also to Table 1, when the interconnected structure 400 is tested under the above testing situations, the above conclusion is applicable to the interconnected structure 400. That is, if a ratio of a contacting area between the first conductive layer 410 and the second conductive layer 430 to a voltage applied thereto is equal to or greater than 0.233 μm²/mv, the interconnected structure 400 is not liable to be corroded.

It is believed that the present embodiments and their advantages will be understood from the foregoing description, and it will be apparent that various changes may be made thereto without departing from the spirit or scope of the invention or sacrificing all of its material advantages, the examples hereinbefore described merely being preferred or exemplary embodiments of the invention.

What is claimed is:

1. An interconnected structure configured for transferring a voltage signal to a thin film transistor (TFT) array substrate, comprising:
a first metal layer;
a second metal layer isolated from the first metal layer; and
a conductive layer isolated from the second metal layer, the first metal layer being electrically connected to the conductive layer via at least one first contact hole thereby obtaining a first contacting area between the first metal layer and the conductive layer, the second metal layer being electrically connected to the conductive layer via at least one second contact hole thereby obtaining a second contacting area between the second metal layer and the conductive layer;
wherein a radio of the sum of the first contacting area and the second contacting area to a voltage value of the voltage signal is equal to or greater than 0.233 μm²/mv.

2. The interconnected structure of claim 1, wherein the radio of the sum of the first contacting area and the second contacting area to the voltage value is 0.250 μm²/mv.

3. The interconnected structure of claim 1, wherein the voltage value of the voltage signal is 5 volts or 3.3 volts.

4. The interconnected structure of claim 3, wherein the sum of the first contacting area and the second contacting area is 1250 μm².

5. The interconnected structure of claim 4, wherein each of the at least one first contact hole has the same contacting area as each of the at least one second contact hole.

6. The interconnected structure of claim 5, wherein the number of the at least one first contact hole is equal to the number of the at least one second contact hole.

7. The interconnected structure of claim 6, wherein the number of the at least one first contact hole is two.

8. The interconnected structure of claim 7, wherein each of the at least one first contact hole and each of the at least one second contact hole are square.

9. The interconnected structure of claim 8, wherein a side length of the at least one first contact hole or a side length of the at least one second contact hole is 20 μm.

10. The interconnected structure of claim 6, wherein the sum of the number of the at least one first contact hole and the number of the at least one second contact hole is twelve.

11. The interconnected structure of claim 10, wherein each of the at least one first contact hole or each of the at least one second contact hole is square.

12. The interconnected structure of claim 11, wherein a side length of the at least one first contact hole or a side length of the at least one second contact hole is 11 μm.

13. The interconnected structure of claim 1, wherein the sum of the first contacting area and the second contacting area is 768 μm².

14. An interconnected structure for transferring a voltage signal to a thin film transistor (TFT) array substrate, comprising:
a first conductive layer; and
a second conductive layer isolated from the first conductive layer, the first conductive layer being electrically connected to the second conductive layer via at least one contact hole;
wherein a radio of the sum of contacting areas between the first conductive layer and the second conductive layer to a voltage value of the voltage signal is equal to or greater than 0.233 μm²/mv.

15. The interconnected structure of claim 14, wherein the radio of the sum of contacting areas to the voltage value is 0.25 μm²/mv.

16. The interconnected structure of claim 14, wherein the voltage value of the voltage signal is 5 volts or 3.3 volts.

17. The interconnected structure of claim 16, wherein the sum of contacting areas is 1250 μm².

18. The interconnected structure of claim 14, wherein the sum of the contacting areas is 768 μm².

19. An interconnected structure for transferring a voltage signal, comprising:
at least two conductive layers isolated from each other, two of the at least two conductive layers contacting each other via at least one contact hole;
wherein a radio of the sum of contacting areas between the two conductive layers contacting each other to a voltage value of the voltage signal is equal to or greater than 0.233 μm²/mv.

20. The interconnected structure of claim 19, wherein the radio of the sum of contacting areas to the voltage value is 0.25 μm²/mv.
